(19) United States
(12) Patent Application Publication
(10) Pub. No.: US 2022/0059605 A1
(43) Pub. Date: Feb. 24, 2022

(54) PIXEL UNIT WITH A DRIVER IC, A LIGHT-EMITTING DEVICE INCLUDING SUCH PIXEL UNITS AND A METHOD FOR MAKING THE LIGHT-EMITTING DEVICE

(71) Applicants: Innostar service Inc., Taichung (TW); Naviance Semiconductor Limited, Hsinchu County (TW)

(72) Inventors: MENG-CHIH WU, Taichung (TW); CHIEN-KUO TIEN, Hsinchu County (TW); CHUN-CHUNG LIN, Hsinchu County (TW)

(21) Appl. No.: 16/999,086

(22) Filed: Aug. 21, 2020

(51) Int. Cl. H01L 27/15; H01L 33/48; H01L 33/62; H01L 33/56; H01L 33/42; H05B 45/325; H01L 33/00

(52) U.S. Cl. CPC H01L 27/156; H01L 33/486; H01L 33/62; H01L 2933/0066; H01L 33/42; H05B 45/325; H01L 33/005; H01L 33/56

(57) ABSTRACT

A method for making a light-emitting device includes providing a driver IC wafer with multiple control circuits. Groups of tiny light-emitting diodes are stacked on the driver IC wafer and electrically connected to the control circuits. Each of the groups comprises a tiny light-emitting diode for emitting red light, a tiny light-emitting diode for emitting green light and a tiny light-emitting diode for emitting blue light. The groups of tiny light-emitting diodes on the driver IC wafer are packaged. The driver IC wafer is cut into driver integrated circuits. Each of the driver integrated circuits includes one of the control circuits electrically connected to one of the groups of tiny light-emitting diodes. Thus, pixel units are provided. The pixel units are transferred to a display substrate and the control circuits of the pixel units are connected to a circuit of the display substrate. Thus, a single light-emitting device is provided.

### BACKGROUND OF INVENTION

### 1. Field of Invention

The present invention relates to displays and, more particularly, to a pixel unit with a driver IC, a light-emitting device with such pixel units and a method for making such pixel units and the light-emitting device.

### 2. Related Prior Art

A conventional display includes multiple light-emitting elements or pixels controlled by a circuit array (or “active array”). The circuit array includes one transistor or more, drivers to control the pixels, and one capacitor or more to maintain biases of the pixels of the display that are updated many times.

The development of liquid crystal displays and plasma displays makes large and durable displays possible. However, there are problems with power efficiency and directionality, and there are problems with power consumption and screen burn-in.

There have been attempts to use organic light-emitting diodes (“OLED”s) in displays. However, the results have not been satisfying. Displays based on OLEDs are less durable and flash. These problems cause manufacturers hesitate about using OLEDs in displays of electronic devices such as smart phones.

Moreover, to manufacture LCD displays, plasma displays and OLED displays, thin-film deposition techniques are used to make control circuits that include thin-film transistors (“TFT”s). In the making of an LCD, the thin-film deposition is used to form 5 to 9 via areas electrically connected to transistors, capacitors and circuits. Control circuits made by TFT techniques are extremely expansive. In addition, TFT deposition techniques require large machines to make large deposition films for large circuit arrays, and hence involve high costs of manufacturing. Hence, only a limited number of manufacturers with huge capitals dare attempt to use TFT techniques.

The present invention is therefore intended to obviate or at least alleviate the problems encountered in the prior art.

### SUMMARY OF INVENTION

It is an objective of the present invention to provide a simple method for making an inexpensive and highly integrated light-emitting device at a low cost.

It is another objective of the present invention to provide a light-emitting device with pixel units that occupy a minimized total area of a face of a display substrate to provide an excellent fill ratio. That is, a total area of transparent portions of the display substrate is maximized. Hence, the light-emitting device is an ideal transparent display that is less expensive than TFT and performs better than LCDs, plasma display and OLED displays.

It is another objective of the present invention to provide a light-emitting device with tiny light-emitting diodes stacked on driver integrated circuits to minimize a distance of electric connection. Surface mount technology is used to attach the driver integrated circuits to a display substrate, and a simple circuit is used to connect the driver integrated circuits to each other to operate the tiny light-emitting diodes. Integration of the tiny light-emitting diodes is better than LCDs, plasma displays and OLED displays.

To achieve the foregoing objectives, the method includes providing a driver IC wafer with control circuits. Groups of tiny light-emitting diodes are stacked on the driver IC wafer and electrically connected to the control circuits. Each of the groups includes a tiny light-emitting diode for emitting red light, a tiny light-emitting diode for emitting green light and a tiny light-emitting diode for emitting blue light. The groups of tiny light-emitting diodes on the driver IC wafer are packaged. The driver IC wafer is cut into driver integrated circuits. Each of the driver integrated circuits includes one of the control circuits electrically connected to one of the groups of tiny light-emitting diodes. Thus, pixel units are provided. The pixel units are transferred to a display substrate and the control circuits of the pixel units are connected to a circuit of the display substrate. Thus, a single light-emitting device is provided.

In another aspect, the method includes the step of providing a combinative light-emitting device by connecting display substrates to one another.

In another aspect, the display substrate is selected from the group consisting of a flexible transparent substrate, a flexible non-transparent substrate, a glass substrate and a printed circuit board.

In another aspect, each of the pixel units includes a driver integrated circuit, a group of three tiny light-emitting diodes and a transparent molding. The driver integrated circuit includes a control circuit. The tiny light-emitting diodes emit red light, green light and blue light respectively. The group of tiny light-emitting diodes is stacked on a face of the driver integrated circuit and electrically connected to the control circuit. The transparent resin molding covers the group of tiny light-emitting diodes and a visible face of the driver integrated circuit.

In another aspect, the control circuit includes a first pin, a second pin, a third pin, a fourth pin, a fifth pin, a pulse width modulator and data lock and a constant current driver. The fourth pin detects and prevents bad-node blocking. The second and fifth pins form a clock data recovery.

In another aspect, the control circuit includes upper bond pads formed on a face of the driver integrated circuit and lower bond pads formed on another face of the driver integrated circuit. Each of upper bond pads is electrically connected to a corresponding one of the lower bond pads by a silicon via.

In another aspect, each of the tiny light-emitting diodes includes an N-electrode and a P-electrode formed on a lower face. The N-electrode and the P-electrode are electrically connected to the upper bond pads of the driver integrated circuit.

In an alternative aspect, each of the tiny light-emitting diodes includes a N-electrode formed on an upper face of the tiny light-emitting diode, a P-electrode formed on a lower face of the tiny light-emitting diode and electrically connected to the control circuit, and a metal wire including an end electrically connected to the control circuit and another end electrically connected to the N-electrode.

In an alternative aspect, each of the tiny light-emitting diodes includes an N-electrode formed on an upper face, a P-electrode formed on a lower face and electrically connected to the control circuit, an ITO transparent conductive film electrically connected to the N-electrode, and a tiny metal rod located next to the tiny light-emitting diodes. The tiny metal rod an end electrically connected to the ITO transparent conductive film and another end electrically connected to the control circuit. The N-electrode, the P-electrode and the tiny metal rod are wrapped by the resin molding.

In another aspect, the light-emitting device includes driver integrated circuits, pixel units and a display substrate. Each of the driver integrated circuits includes a control circuit. Each of the pixel units includes a group of tiny light-emitting diodes and a transparent resin molding. In the group, the tiny light-emitting diodes emit red light, green light and blue light respectively. The group of tiny light-emitting diodes is stacked on a corresponding one of the driver integrated circuits and electrically connected to the control circuit of the corresponding driver integrated circuit. The transparent resin molding covers the group of tiny light-emitting diodes and a visible face of the corresponding driver integrated circuit. The display substrate including a modular connector and a circuit for connecting the modular connector to the multiple pixel units.

In another aspect, a combinative light-emitting device includes light-emitting devices as described above and a controller for electrically connected to the modular connectors of the display substrates.

Other objectives, advantages and features of the present invention will be apparent from the following description referring to the attached drawings.

### BRIEF DESCRIPTION OF DRAWINGS

The present invention will be described via detailed illustration of three embodiments referring to the drawings wherein:

FIG. 1 is a flow chart of a method for making a light-emitting device according to the present invention;

FIG. 2 is a perspective view of a wafer made according to the method shown in FIG. 1;

FIG. 3 is a perspective view of multiple light-emitting diodes cut from the wafer shown in FIG. 2;

FIG. 4 is a perspective view of multiple light-emitting diodes on a driver IC wafer;

FIG. 5 is a top view of a pixel unit according to the first embodiment according to the present invention;

FIG. 6 is a front view of the pixel unit shown in FIG. 5;

FIG. 7 is a block diagram of a control circuit of a driver IC;

FIG. 8 is a top view of a light-emitting device including multiple pixel units as shown in FIG. 5;

FIG. 9 is a top view of multiple light-emitting devices as depicted in FIG. 8;

FIG. 10 is a perspective view of a pixel unit according to the second embodiment according to the present invention;

FIG. 11 is a front view of the pixel unit shown in FIG. 10; and

FIG. 12 is a front view of a pixel unit according to the third embodiment according to the present invention.

### DETAILED DESCRIPTION OF EMBODIMENTS

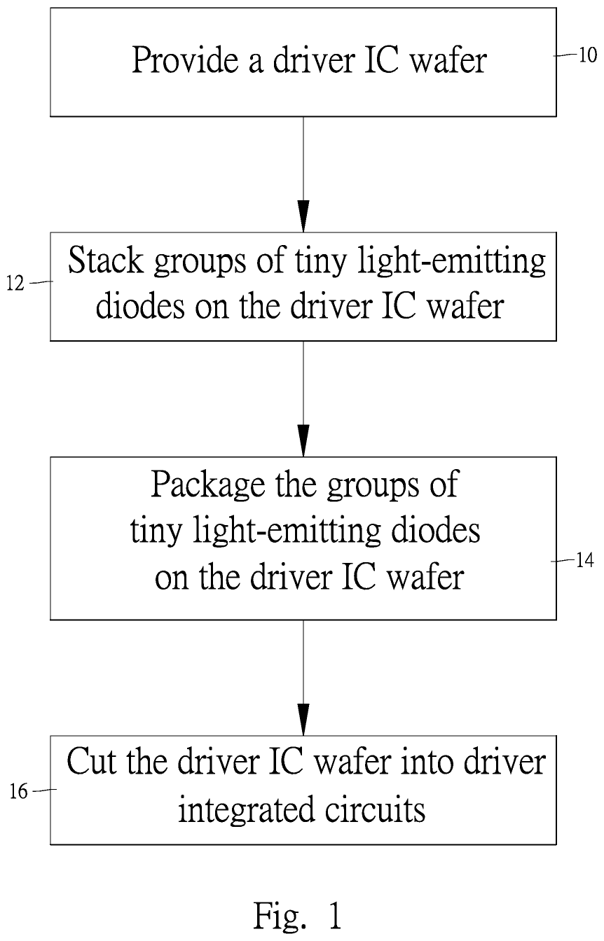

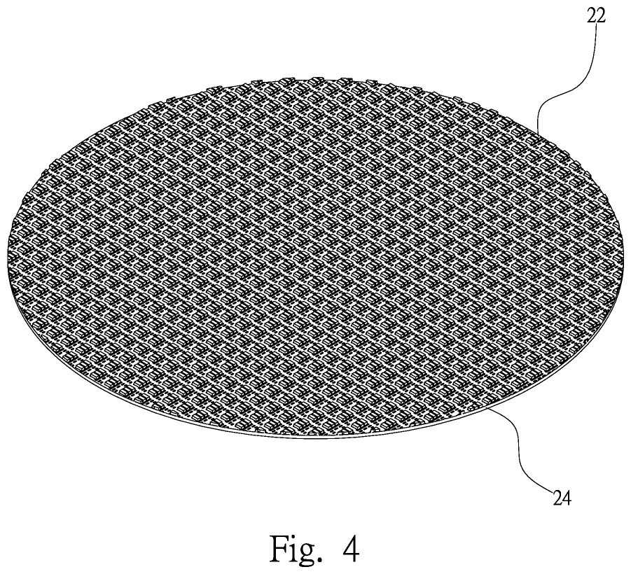

Referring to FIGS. 1 through 4, a light-emitting device is made in a method according to the present invention.

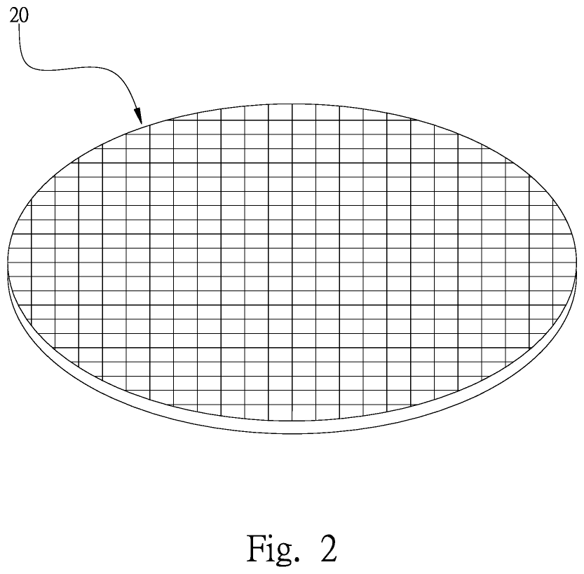

Referring to FIG. 2, an LED wafer 20 is provided.

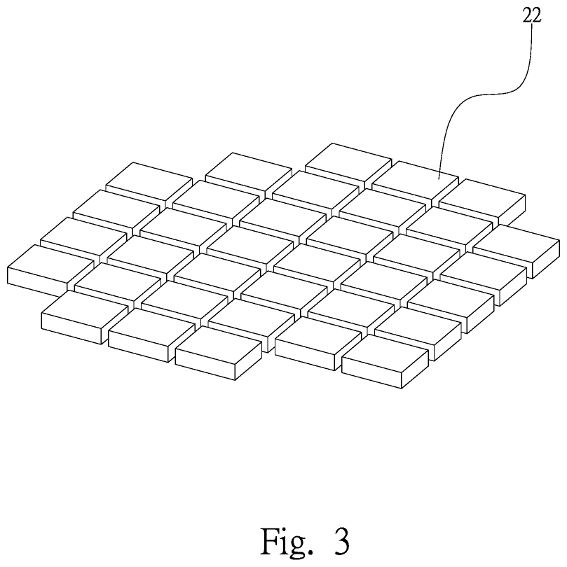

Referring to FIG. 3, laser is used to cut the LED wafer 20 into tiny light-emitting diodes 22. The size of the tiny light-emitting diodes 22 is smaller than 100 μm, and the thickness of the tiny light-emitting diodes 22 is smaller than 50 μm. The tiny light-emitting diodes 22 are different from ordinary light-emitting diodes with a size of 100 to 1000 μm and a thickness of 100 to 500 μm.

The process shown in FIGS. 2 and 3 is repeated for three times to respectively make tiny light-emitting diodes 22 for emitting red light, tiny light-emitting diodes 22 for emitting green light and tiny light-emitting diodes 22 for emitting blue light.

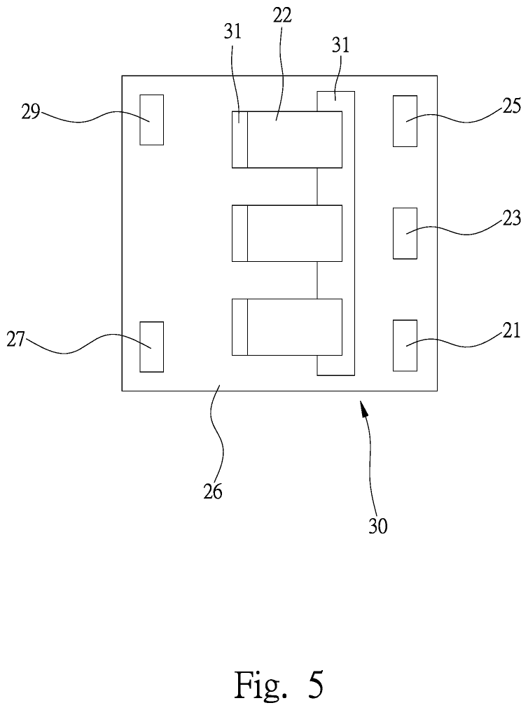

At 10, a driver IC wafer 24 is provided. The driver IC wafer 24 includes multiple areas corresponding to multiple driver integrated circuits 26 (FIGS. 5, 10 and 12). Each of the driver integrated circuits 26 includes a control circuit 40.

At 12, the tiny light-emitting diodes 22 are sorted into groups. Each of the groups includes an LED 22 for emitting red light, an LED 22 for emitting green light and an LED 22 for emitting blue light. The groups of tiny light-emitting diodes 22 are located on the driver IC wafer 24. Each of the groups of tiny light-emitting diodes 22 is electrically connected to a corresponding one of the driver integrated circuits 26 before packaging. Then, the tiny light-emitting diodes 22 and the driver IC wafer 24 are packaged by a 3D integration-through-stacked-die packaging technique. Chip scale packaging (“CSP”) is executed on the tiny light-emitting diodes 22 in the form of a flip chip.

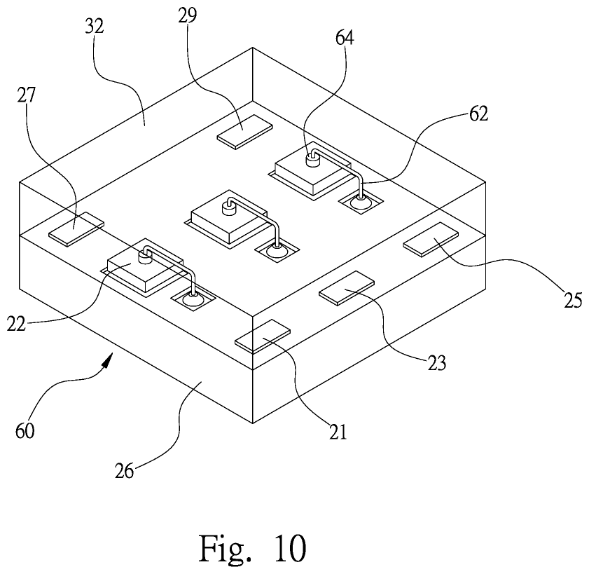

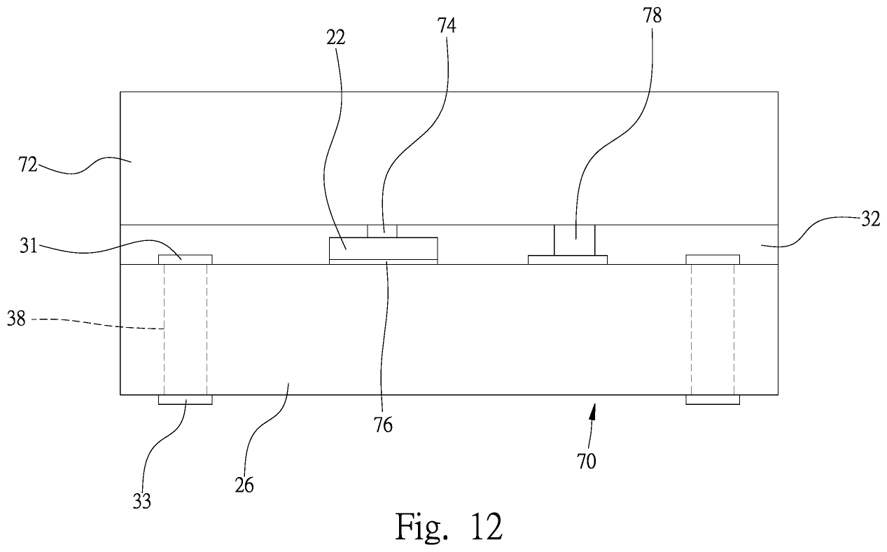

At 14, laser is used to cut the driver IC wafer 24 into the driver integrated circuits 26 after the packaging. The control circuit 40 of each of the driver integrated circuits 26 is electrically connected to a corresponding one of the tiny light-emitting diodes 22 to provide a pixel unit 30 (FIG. 5), a pixel unit 60 (FIG. 10) or a pixel unit 70 (FIG. 12).

At 16, the pixel units 30, 50 or 70 are transferred to a display substrate and electrically connected to one another by a circuit of the display substrate to provide a single light-emitting device. The circuits of multiple display substrates can be electrically connected to one another to provide a combinative light-emitting device.

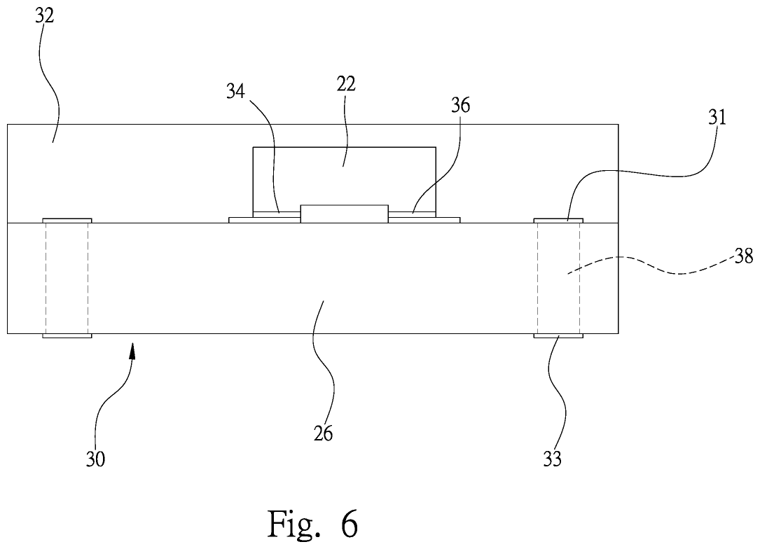

Referring to FIGS. 5 and 6, there is shown one of the pixel units 30 according to a first embodiment of the present invention. As described above, the pixel unit 30 includes one driver integrated circuit 26 and one group of tiny light-emitting diodes 22. The group of tiny light-emitting diodes 22 is stacked on the driver integrated circuit 26 so that a distance of electric connection is minimized.

The driver integrated circuit 26 of the pixel unit 30 includes five pins 21, 23, 25, 27 and 29, upper bond pads 31, lower bond pads 33 and silicon vias 38. The upper bond pads 31 are formed on an upper face of each of the driver integrated circuits 26 of the driver IC wafer 24. The lower bond pads 33 are formed on a lower face of each of the driver integrated circuits 26 of the driver IC wafer 24.

The silicon vias 38 are made in the driver IC wafer 24 in a through-silicon-via (“TSV”) process. Each of the silicon vias 38 allows vertical connection of a corresponding one of the upper bond pads 31 to a corresponding one of the lower bond pads 33. The upper bond pads 31 and the lower bond pads 33 provide pins for the control circuit 40.

Each of the pins 21, 23, 25, 27 and 29 is electrically connected to a corresponding one of the lower bond pads 33 by a corresponding one of the silicon vias 38.

A transparent resin molding 32 is used to cover the group of tiny light-emitting diodes 22 and a visible face of the driver IC 26 after the group of tiny light-emitting diodes 22 is electrically connected to the control circuit 40 of the driver IC 26.

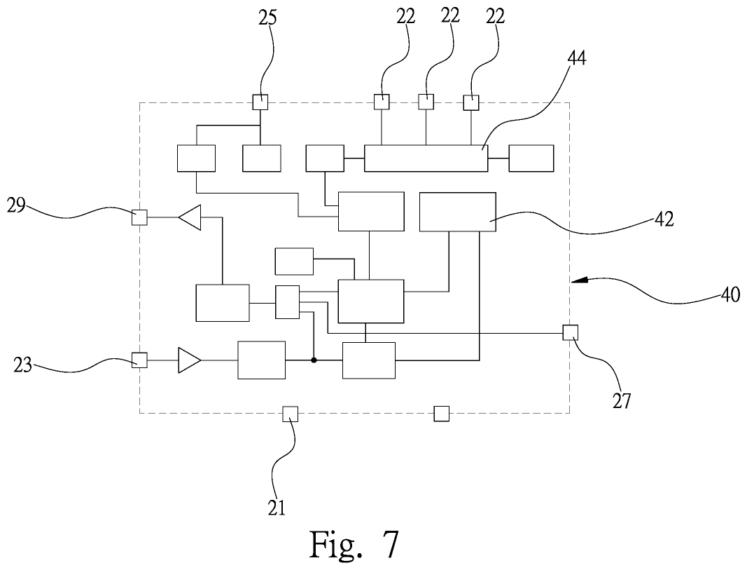

Each of the tiny light-emitting diodes 22 includes an N-electrode 34 and a P-electrode 36 formed on a same face. The N-electrode 34 and the P-electrode 36 are electrically connected to the upper bond pads 31 of the corresponding driver IC 26 to form a simple loop. Hence, the control circuit 40 of the driver IC 26 (FIG. 7) is electrically connected to the group of tiny light-emitting diodes 22. The 3D integration-through-stacked-die packaging technique is used to package the group of tiny light-emitting diodes 22 and the driver IC 26 to provide the pixel unit 30.

Referring to FIGS. 5 and 7, each driver IC 26 is grounded via the first pin 21. The second pin 23 is an input terminal and the fifth pin 29 is an output terminal to form a clock data recovery to allow the driver integrated circuits 26 to connect to one another for display data communication. Each driver IC 26 receives electricity via the third pin 25. The fourth pin 27 detects any damage of any driver IC 26 to exclude any broken driver IC 26 from the loop and connects to a next formal driver IC 26. Thus, the fourth pin 27 detects and prevents bad-node blocking to render the following operation smooth.

The control circuit 40 of the driver IC 26 includes a pulse width modulator and data lock 42 and a constant current driver 44. The constant current driver 44 is electrically connected to the corresponding group of tiny light-emitting diodes 22 to overcome problems of changed wavelengths in analog dimming and uneven brightness.

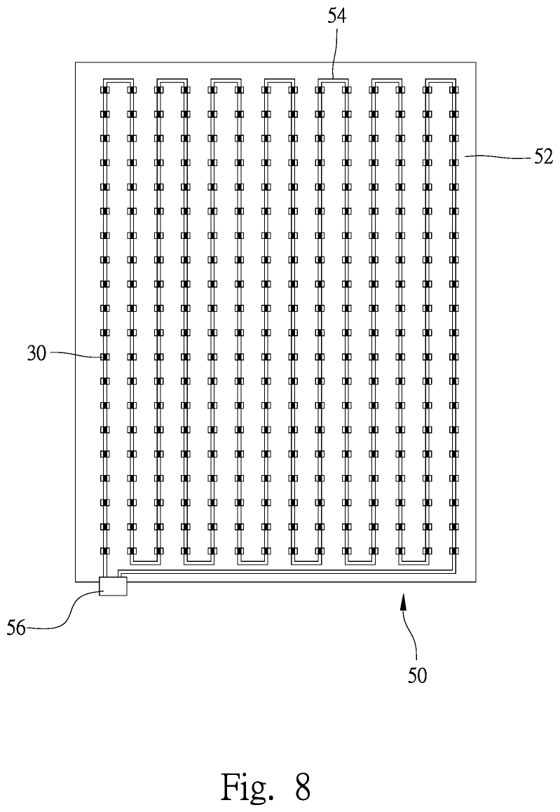

Referring to FIG. 8, multiple pixel units 30 are transferred onto a display substrate 52. SMT is used to attach the driver integrated circuits 26 to the display substrate 52. The display substrate 52 includes a simple circuit 54 to electrically connect the pixel units 30 to one another and to a modular connector 56 to receive electricity. Therefore, a light-emitting device 50 is made, and the step represented by “16” is completed. The light-emitting device 50 is a single light-emitting device to actuate the tiny light-emitting diodes 22 to emit light. The light-emitting device 50 exhibits excellent integration.

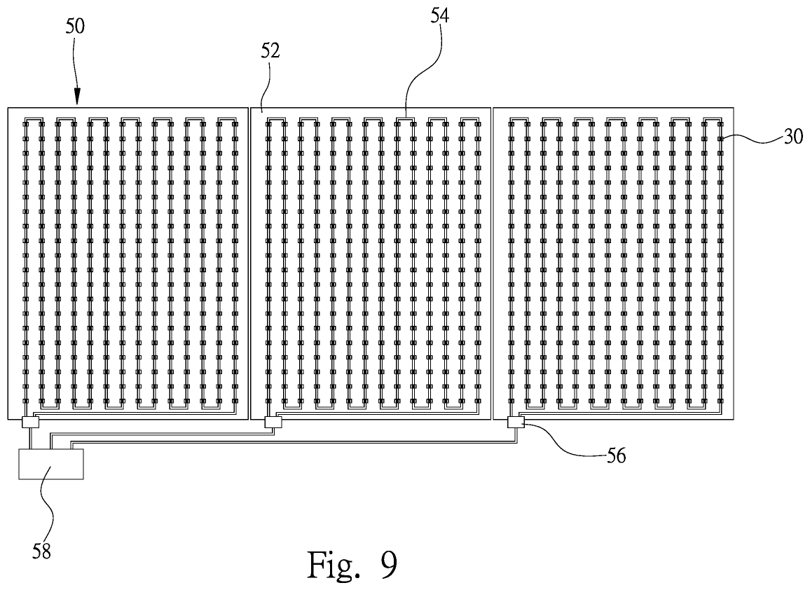

Referring to FIG. 9, a controller 58 is electrically connected to multiple modular connectors 56 to electrically multiple display substrates 52 to one another. Thus, a combinative light-emitting device 50 is made, and the step represented by “16” is completed.

The area of an upper face of the display substrate 52 occupied by the pixel units 30 is minimized to provide an excellent fill ratio so that the area of transparent portions of the display substrate 52 is maximized. Therefore, the light-emitting device 50 is an ideal transparent display.

The display substrate 52 is a flexible transparent substrate, a flexible non-transparent substrate, glass substrate or a PCB.

The step represented by “12” can be executed to make the light-emitting elements 30 according to the first embodiment of the present invention. To this end, the step represented by “12” includes several steps to be described.

Firstly, conductive silver or tin paste is provided on the areas of the driver IC wafer 24 corresponding to the tiny light-emitting diodes 22.

Secondly, the groups of tiny light-emitting diodes 22 are transferred onto the areas of the driver IC wafer 24 wherein the conductive silver or tin paste is provided.

Thirdly, a bonding operation based on heating and curing is executed to connect a N-electrode 34 and a P-electrode 36 of each tiny LED 22 to the upper bond pads 31 of the control circuit 40 of the corresponding driver IC 26 by soldering.

Fourthly, the resin molding 32 is heated to attach the tiny light-emitting diodes 22 to the upper face of the driver IC wafer 24.

Then, the step represented by “14” is taken to cut the driver IC wafer 24 into the pixel units 30.

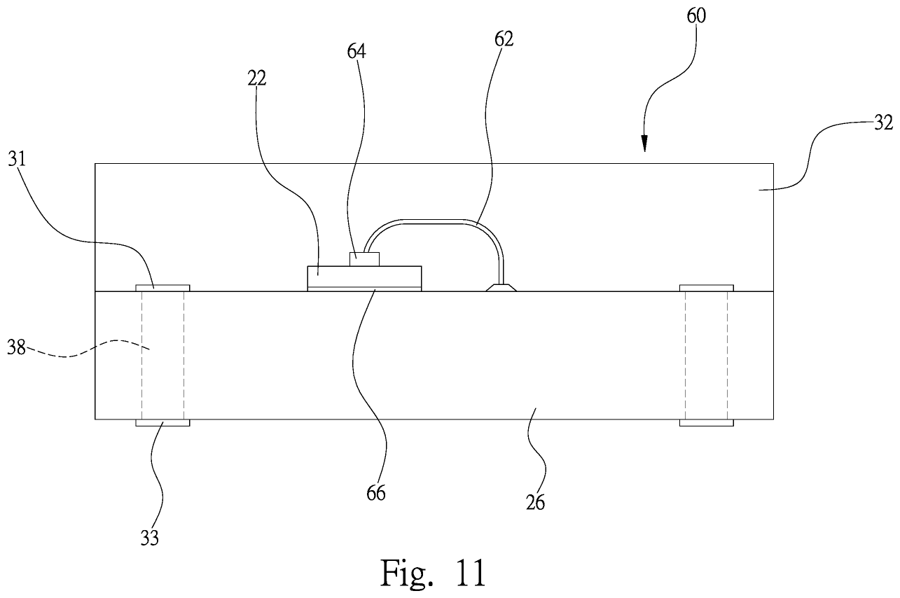

Referring to FIGS. 10 and 11, a pixel unit 60 according to a second embodiment of the present invention is shown. The pixel unit 60 includes a metal wire 62. In the pixel unit 60, the tiny LED 22 includes an N-electrode 64 and a P-electrode 66. The N-electrode 64 is formed on the upper face of the tiny LED 22. The P-electrode 66 is formed on the lower face of the tiny LED 22. An end of the metal wire 62 is electrically connected to the N-electrode 64. Another end of the metal wire 62 is electrically connected to the control circuit 40 of the driver IC 26 (FIG. 7). The control circuit 40 is electrically connected to the P-electrode 66. Thus, an electric loop is formed. The resin molding 32 wraps the tiny LED 22 and the metal wire 62. The pixel unit 60 is otherwise identical to the pixel units 30.

The step represented by “12” can be taken to make pixel units 60 according to the second embodiment. A chip-on-board (“COB”) technique is executed on the tiny light-emitting diodes 22 for packaging. Accordingly, the step represented by “12” includes several steps to be described.

Firstly, conductive silver or tin paste is provided on the areas of the driver IC wafer 24 corresponding to the tiny light-emitting diodes 22.

Secondly, the groups of tiny light-emitting diodes 22 are transferred onto the areas of the driver IC wafer 24 wherein the conductive silver or tin paste is provided.

Thirdly, a bonding operation based on heating and curing is executed to connect the P-electrode 66 of each tiny LED 22 to a pin (not numbered) of the control circuit 40 of the corresponding driver IC 26 by soldering.

Fourthly, conductive silver or tin paste is provided on the N-electrode 64 of the tiny LED 22 and a pin of the control circuit 40 of the corresponding driver IC 26.

Fifthly, an end of the metal wire 62 is connected to the N-electrode 64 of each tiny LED 22 by conductive silver or tin paste, and the other end of the metal wire 62 is connected to the pin of the control circuit 40 of the corresponding driver IC 26 by conductive silver or tin paste.

Sixthly, resin molding is heated and cured to secure each tiny LED 22 to the upper face of the driver IC wafer 24.

Then, the step represented by “14” is taken to use laser to cut the driver IC wafer 24 into the pixel units 60.

Referring to FIG. 12, a pixel unit 70 according to a third embodiment of the present invention is shown. The pixel unit 70 includes an ITO transparent conductive film 72 and a tiny metal rod 78. In the pixel unit 70, the tiny LED 22 includes an N-electrode 74 formed on an upper face of the tiny LED 22 and a P-electrode 76 formed on the lower face of the tiny LED 22. The N-electrode 74 is electrically connected to the ITO transparent conductive film 72. The P-electrode 76 is electrically connected to the control circuit 40 of the driver IC 26. The tiny metal rod 78 is located next to the tiny LED 22. An end of the tiny metal rod 78 is electrically connected to the ITO transparent conductive film 72. Another end of the tiny metal rod 78 is electrically connected to the control circuit 40 of the driver IC 26. Thus, an electric loop is formed. Moreover, the resin molding 32 attaches the driver IC 26 to the ITO transparent conductive film 72 and wraps the tiny LED 22 and the tiny metal rod 78. The pixel unit 70 is otherwise identical to the pixel units 30.

The step represented by “12” can be taken to make the light-emitting elements according to the third embodiment. A transparent conductive film technique such as an ITO technique is executed on the tiny light-emitting diodes 22. To this end, the step represented by “12” includes several steps to be described.

Firstly, conductive silver or tin paste is provided on the areas of the driver IC wafer 24 corresponding to the tiny light-emitting diodes 22.

Secondly, the groups of tiny light-emitting diodes 22 and multiple tiny metal rods 78 are transferred onto the driver IC wafer 24.

Thirdly, a bonding operation based on heating and curing is executed to connect the P-electrode 76 of each tiny LED 22 to a pin (not numbered) of the control circuit 40 of the corresponding driver IC 26 by soldering. The tiny metal rod 78 of each pixel unit 70 is located next to the tiny LED 22 and connected to the upper bond pads 31 of the control circuit 40 of the corresponding driver IC 26.

Fourthly, the ITO transparent conductive film 72 is attached to an upper face of the resin molding 32. In a common-cathode method, the N-electrode 74 of the tiny LED 22 is connected to the tiny metal rod 78.

Then, the step represented by “14” is taken to use laser to cut the driver IC wafer 24 into the pixel units 70.

The present invention has been described via the illustration of the embodiments. Those skilled in the art can derive variations from the embodiments without departing from the scope of the present invention. Therefore, the embodiments shall not limit the scope of the present invention defined in the claims.

1. A method for making a light-emitting device comprising the steps of:
providing a driver IC wafer with control circuits;
providing groups of tiny light-emitting diodes on the driver IC wafer and electrically connecting the groups of tiny light-emitting diodes to the control circuits, wherein each of the groups comprises a tiny light-emitting diode for emitting red light, a tiny light-emitting diode for emitting green light and a tiny light-emitting diode for emitting blue light;
packaging the groups of tiny light-emitting diodes on the driver IC wafer;
providing 3D integration-through-stacked-die-packaging pixel units by cutting the driver IC wafer into driver integrated circuits, wherein each of the driver integrated circuits comprises one of the control circuits electrically connected to one of the groups of tiny light-emitting diodes; and
providing a single light-emitting device by transferring the pixel units to a display substrate and connecting the control circuits of the pixel units to a circuit of the display substrate.

2. The method according to claim 1, comprising the step of providing a combinative light-emitting device by connecting display substrates to one another.

3. The method according to claim 1, wherein the display substrate is selected from the group consisting of a flexible transparent substrate, a flexible non-transparent substrate, a glass substrate and a printed circuit board.

4. A pixel unit comprising:
a driver IC comprising a control circuit;
a group of three tiny light-emitting diodes for emitting red light, green light and blue light respectively, wherein the group of tiny light-emitting diodes is stacked on a face of the driver IC and electrically connected to the control circuit; and
a transparent resin molding for covering the group of tiny light-emitting diodes and a visible face of the driver IC.

5. The pixel unit according to claim 4, wherein the control circuit comprises:
a first pin;
a second pin;
a third pin;
a fourth pin for detecting and preventing bad-node blocking;
a fifth pin, wherein the second and fifth pins form a clock data recovery;
a pulse width modulator and data lock; and
a constant current driver.

6. The pixel unit according to claim 4, wherein the control circuit comprises upper bond pads formed on a face of the driver IC, lower bond pads formed on another face of the driver IC, wherein each of upper bond pads is electrically connected to a corresponding one of the lower bond pads by a silicon via.

7. The pixel unit according to claim 6, wherein each of the tiny light-emitting diodes comprises a N-electrode and a P-electrode formed on a lower face, wherein the N-electrode and the P-electrode are electrically connected to the upper bond pads of the driver IC.

8. The pixel unit according to claim 6, wherein each of the tiny light-emitting diodes comprises:
a N-electrode formed on an upper face of the tiny light-emitting diode;
a P-electrode formed on a lower face of the tiny light-emitting diode and electrically connected to the control circuit; and
a metal wire comprising an end electrically connected to the control circuit and another end electrically connected to the N-electrode.

9. The pixel unit according to claim 6, wherein each of the tiny light-emitting diodes comprises:
a N-electrode formed on an upper face of the tiny light-emitting diode;
a P-electrode formed on a lower face of the tiny light-emitting diode and electrically connected to the control circuit;
an ITO transparent conductive film electrically connected to the N-electrode; and
a tiny metal rod located next to the tiny light-emitting diodes and formed with an end electrically connected to the ITO transparent conductive film and another end electrically connected to the control circuit, wherein the N-electrode, the P-electrode and the tiny metal rod are wrapped by the resin molding.

10. A light-emitting device comprising:
driver integrated circuits each of which comprises a control circuit;
pixel units each of which comprises:
a group of tiny light-emitting diodes for emitting red light, green light and blue light respectively, wherein the group of tiny light-emitting diodes is stacked on a corresponding one of the driver integrated circuits and electrically connected to the control circuit of the corresponding driver integrated circuit; and
a transparent resin molding for covering the group of tiny light-emitting diodes and a visible face of the corresponding driver integrated circuit; and
a display substrate comprising a modular connector and a circuit for connecting the modular connector to the multiple pixel units.

11. A combinative light-emitting device comprising light-emitting devices according to claim 10 and a controller for electrically connected to the modular connectors of the display substrates.
